(19) United States
(12) Patent Application Publication
(10) Pub. No.: US 2026/0020440 A1
(43) Pub. Date: Jan. 15, 2026

(54) LIGHT-EMITTING PANEL AND MANUFACTURING METHOD, AND LIGHT-EMITTING DEVICE

(71) Applicants: Beijing BOE Technology Development Co., Ltd., Beijing (CN); BOE TECHNOLOGY GROUP CO., LTD., Beijing (CN)

(72) Inventors: Shuangshuang SHI, Beijing (CN); Youqin ZHU, Beijing (CN); Dong LI, Beijing (CN); Yichi ZHANG, Beijing (CN)

(73) Assignees: Beijing BOE Technology Development Co., Ltd., Beijing (CN); BOE TECHNOLOGY GROUP CO., LTD., Beijing (CN)

(21) Appl. No.: 18/995,168

(22) PCT Filed: May 16, 2024
(86) PCT No.: PCT/CN2024/093712

§ 371 Date: Jan. 16, 2025

(30) Foreign Application Priority Data
Jun. 2, 2023 (CN) 202310653886.9

(51) Int. Cl. H10K 59/122; H10K 50/165; H10K 59/12

(52) U.S. Cl. CPC H10K 59/122; H10K 50/165; H10K 59/1201

(57) ABSTRACT

A light-emitting panel includes a pixel definition layer and a specific carrier transport layer. The pixel definition layer has pixel openings. The specific carrier transport layer includes first portions and a second portion; a first portion is located in a pixel opening, and the second portion is connected between at least two first portions; and the second portion doped with a first material is configured to play a role of conductivity isolation for the at least two first portions.

### CROSS-REFERENCE TO RELATED APPLICATIONS

This application is a national phase entry under 35 USC 371 of International Patent Application No. PCT/CN2024/093712, filed on May 16, 2024, which claims priority to Chinese Patent Application No. 202310653886.9, filed on Jun. 2, 2023, which are incorporated herein by reference in their entirety.

### TECHNICAL FIELD

The present disclosure relates to the field of display technologies, and in particular, to a light-emitting panel and a manufacturing method, and a light-emitting device.

### BACKGROUND

Display panels, such as organic light-emitting diode (OLED) display panels, have self-luminescence, lightness and thinness, low power consumption, sensitive response, wide viewing angle, and other advantages, and have broad development prospects.

### SUMMARY

In an aspect, a light-emitting panel is provided. The light-emitting panel includes a pixel definition layer and a specific carrier transport layer. The pixel definition layer has a plurality of pixel openings. The specific carrier transport layer includes first portions and a second portion, a first portion is located in a pixel opening, and the second portion is connected between at least two first portions. The second portion doped with a first material is configured to play a role of conductivity isolation for the at least two first portions.

In some embodiments, the specific carrier transport layer includes a pn junction formed by the second portion doped with the first material and the first portion, and the pn junction is configured to play a role of conductivity isolation for the at least two first portions.

In some embodiments, a doping concentration of the first material is in a range of 10¹⁷ cm⁻¹ to 10²⁰ cm⁻¹.

In some embodiments, the specific carrier transport layer includes a compensation semiconductor formed by the second portion doped with the first material, and the compensation semiconductor is configured to play a role of conductivity isolation for the at least two first portions.

In some embodiments, a doping concentration of the first material is in a range of 0.1 cm⁻¹ to 10¹⁷ cm⁻¹, a ratio of a carrier concentration of the first material to a carrier concentration of the specific carrier transport layer is in a range of 0.9 to 1.1.

In some embodiments, a material for forming the specific carrier transport layer includes a p-type semiconductor, and a cation valence of the first material is greater than a cation valence of the material for forming the specific carrier transport layer.

In some embodiments, a material for forming the specific carrier transport layer includes a p-type semiconductor, and an anion valence of the first material is greater than an anion valence of the material for forming the specific carrier transport layer.

In some embodiments, a material of the specific carrier transport layer includes an n-type semiconductor, and a cation valence of the first material is smaller than a cation valence of the specific carrier transport layer.

In some embodiments, a material of the specific carrier transport layer includes an n-type semiconductor, and an anion valence of the first material is smaller than an anion valence of the specific carrier transport layer.

In some embodiments, the first material includes at least one of carbon, silicon, germanium, tin, plumbum, and flerovium.

In some embodiments, a cation valence of the first material is the same as a cation valence of the specific carrier transport layer, and a band gap of a material formed by cations of the first material and anions of a material for forming the specific carrier transport layer is greater than a band gap of the specific carrier transport layer.

In some embodiments, an anion valence of the first material is the same as an anion valence of the specific carrier transport layer, and a band gap of a material formed by anions of the first material and cations of a material for forming the specific carrier transport layer is greater than the band gap of the specific carrier transport layer.

In some embodiments, the first portion is a portion doped with a first material, and a doping concentration of the first material in the second portion is greater than a doping concentration of the first material in the first portion.

In some embodiments, the second portion includes two inclined surfaces and a transition surface located between the two inclined surfaces.

In some embodiments, in a direction from a middle of the second portion to an end of the second portion, a doping concentration of the first material in the second portion decreases sequentially.

In some embodiments, the light-emitting panel further includes a light-emitting layer, and the light-emitting layer is stacked with the specific carrier transport layer. In a direction from the specific carrier transport layer to the light-emitting layer, a doping concentration of the first material in the second portion decreases successively.

In some embodiments, a surface roughness of a surface of the specific carrier transport layer away from the pixel definition layer is in a range of 0 to 5 nm.

In some embodiments, a material of the specific carrier transport layer is an inorganic material.

In some embodiments, the light-emitting panel further includes: a first electrode, a first carrier transport layer, a light-emitting layer, a second carrier transport layer, and a second electrode that are stacked in sequence. A material of the light-emitting layer is quantum dots. The specific carrier transport layer is at least one of the first carrier transport layer and the second carrier transport layer.

In another aspect, a manufacturing method for a light-emitting panel is provided, and the method includes: forming a pixel definition layer, the pixel definition layer having pixel openings; forming a specific carrier transport layer on the pixel definition layer, the specific carrier transport layer including first portions and a second portion, a first portion being located in a pixel opening, and the second portion being connected between at least two first portions; and performing a doping process on an initial portion of the specific carrier transport layer with a first material to form the second portion, so that the second portion plays a role of conductivity isolation for the at least two first portions.

In some embodiments, after forming the specific carrier transport layer on the pixel definition layer, and before performing the doping process on the initial portion of the specific carrier transport layer with the first material, the method further includes: providing a mask on a side of the specific carrier transport layer away from the pixel definition layer, the mask having hollow regions, and a hollow region being directly opposite to the initial portion.

In some embodiments, before providing the mask on the side of the specific carrier transport layer away from the pixel definition layer, the method further includes: forming a photoresist layer on the side of the specific carrier transport layer away from the pixel definition layer, the photoresist layer being located between the specific carrier transport layer and the mask. After providing the mask on the side of the specific carrier transport layer away from the pixel definition layer and before the step of performing the doping process on the second portion with the first material, the method further includes: removing a portion of the photoresist layer directly opposite to the initial portion by using the hollow region of the mask, so as to expose the initial portion. After the step of performing the doping process on the second portion with the first material, the method further includes: removing the photoresist layer.

In some embodiments, performing the doping process on the initial portion with the first material includes: performing the doping process on the initial portion with the first material by ion implantation.

In yet another aspect, a light-emitting device is provided. The light-emitting device includes the light-emitting panel described above.

### BRIEF DESCRIPTION OF THE DRAWINGS

In order to describe technical solutions in some embodiments of the present disclosure more clearly, the accompanying drawings to be used in some embodiments of the present disclosure will be introduced briefly; obviously, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a light-emitting device, in accordance with some embodiments;

FIG. 2 is a structural diagram of a light-emitting panel, in accordance with some embodiments;

FIG. 3 is a structural diagram of another light-emitting panel, in accordance with some embodiments;

FIG. 4 is a flow diagram of a manufacturing method of a light-emitting panel, in accordance with some embodiments;

FIG. 5 is a process diagram of a manufacturing method for a light-emitting panel, in accordance with some embodiments;

FIG. 6 is a flow diagram of a manufacturing method of another light-emitting panel, in accordance with some embodiments;

FIGS. 7 to 9 are process diagrams of a manufacturing method for another light-emitting panel, in accordance with some embodiments;

FIG. 10 is a flow diagram of a manufacturing method of yet another light-emitting panel, in accordance with some embodiments; and

FIGS. 11 to 16 are process diagrams of a manufacturing method for yet another light-emitting panel, in accordance with some embodiments.

### DETAILED DESCRIPTION

The technical solutions in some embodiments of the present disclosure will be described clearly and completely with reference to the accompanying drawings; obviously, the described embodiments are merely some but not all embodiments of the present disclosure. All other embodiments obtained by a person having ordinary skill in the art based on the embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

The terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “multiple”, “a plurality of” or “the plurality of” means two or more unless otherwise specified.

Some embodiments may be described using the terms “coupled”, “connected” and their derivatives. The term “connected” or “connection” shall be understood in a broad sense. For example, the term “connected” may represent a fixed connection, or a detachable connection, or a one-piece connection; alternatively, the term “connected” may represent a direct connection, or an indirect connection through an intermediate medium. For example, the term “coupled” indicates that two or more components are in direct physical or electrical contact. The term “coupled” or “communicatively coupled” may also mean that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, a difference between two equals being less than or equal to 5% of either of the two equals.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views that are schematic illustrations of idealized embodiments. In the drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

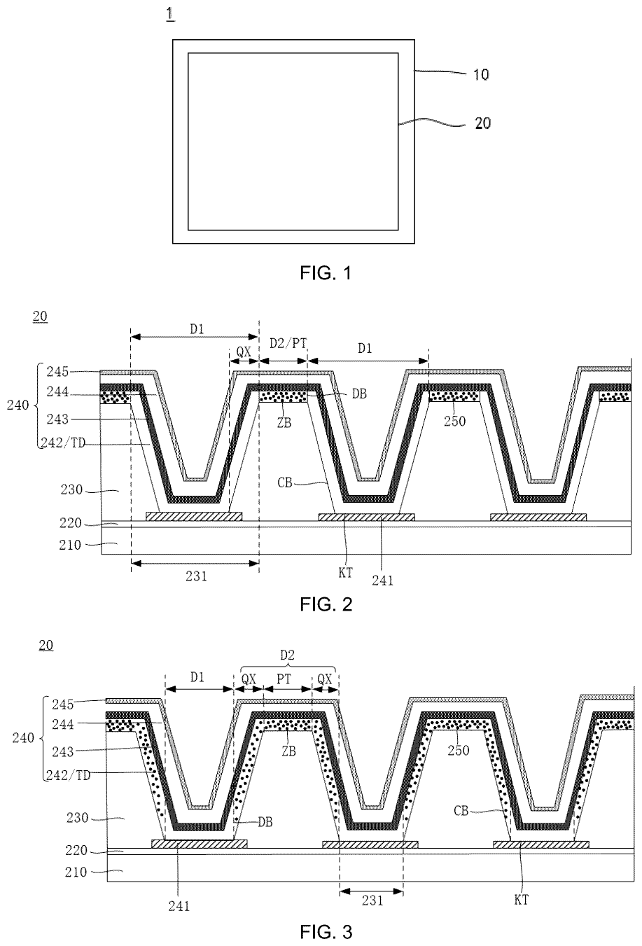

Some embodiments of the present disclosure provide a light-emitting device 1. Referring to FIG. 1, the light-emitting device 1 includes a light-emitting panel 20. For example, the light-emitting device 1 may include a controller for providing electrical signals for the light-emitting panel 20 to drive the light-emitting panel 20 to emit light. For example, the controller may be a central processing unit (CPU) or a graphics processing unit (GPU). The light-emitting device 1 may further include a frame 10 and the like; the frame 10 is configured to fix the light-emitting panel 20, and the controller.

In some embodiments, the light-emitting device 1 may be a lighting device. In this case, the light-emitting device 1 serves as a light source for achieve the function of lighting. For example, the light-emitting device 1 may be a backlight module in a liquid crystal display apparatus, a lamp for internal or external illumination, or various signal lamps.

In some other embodiments, the light-emitting device 1 may be a display device. In this case, the light-emitting panel 20 is a display panel for realizing the function of displaying images (i.e., a picture). The display device is a product having an image (including a still image or a moving image, where the moving image may be a video) display function. The display device may be, for example, a virtual reality (VR) display device or an augmented reality (AR) display device. Alternatively, the display device may be, for example, a display, a mobile phone, a pad, a laptop computer, a television, a personal digital assistant (PDA), an ultra-mobile personal computer (UMPC), a netbook, a wearable device (e.g., a smart watch), or an in-vehicle display device, and the type of the display device is not limited in the embodiments.

For example, in a case where the light-emitting panel 20 is a display panel, the light-emitting panel 20 may have a display area and a non-display area. The display area of the display panel is an area of the display panel capable of displaying images. An area of the display panel 2 except for the display area is the non-display area. The non-display area may be located on at least one side (e.g., one side or multiple sides) of the display area.

Referring to FIG. 2, the light-emitting panel 20 includes a pixel definition layer 230 and a plurality of light-emitting devices 240. The pixel definition layer 230 has a plurality of pixel openings 231. The plurality of light-emitting devices 240 are arranged in one-to-one correspondence with the plurality of light-emitting devices 231. The light-emitting device 240 is a device capable of emitting light after being powered on. For example, the plurality of light-emitting devices 240 may include at least one of red light-emitting devices 240, green light-emitting devices 240, and blue light-emitting devices 240.

For example, the light-emitting panel 20 further includes a substrate 210 and a circuit structure layer 220.

The substrate 210 may be made of an inorganic material, an organic material, a silicon wafer or a composite material layer, etc. The inorganic material may be, for example, glass, or metal; the organic material may be, for example, polycarbonate, polymethyl methacrylate, polyethylene terephthalate, polyethylene naphthalate, polyamide, polyether sulfone, or a combination thereof.

The circuit structure layer 220 is disposed on the substrate 210. That is, as shown in FIG. 2, the substrate 210, the circuit structure layer 220, the pixel definition layer 230, and the plurality of light-emitting devices 240 are stacked in sequence.

The circuit structure layer 220 includes pixel driving circuits for driving the respective light-emitting devices 240 to emit light; that is, a pixel driving circuit is electrically connected to a light-emitting device 240. The pixel driving circuit is configured to provide an electrical signal with an adjustable magnitude for the light-emitting device 240, so that the luminance of the light-emitting device 240 is adjustable.

In some examples, the pixel driving circuit may include a plurality of transistors and at least one (e.g., one or more) capacitor. For example, each pixel driving circuit ay includes two transistors and one capacitor to constitute a 2T1C structure. Alternatively, the pixel driving circuit includes more than two transistors and at least one capacitor to constitute, for example, a 3T1C structure (i.e., three transistors, and one capacitor), a 4T1C structure (i.e., four transistors, and one capacitor), a 5T1C structure (i.e., five transistors and one capacitor), a 7T1C structure (i.e., seven transistors and one capacitors), or a 11T3C structure (i.e., eleven transistors, and three capacitor).

The transistors in the embodiments of the present disclosure are all illustrated by thin film transistors, but are not limited to thin film transistors, and may also be field effect transistors, etc.

The transistor includes a gate, a source, a drain, and an active pattern connected between the source and drain. The material of the active pattern may include an oxide semiconductor; for example, the oxide semiconductor may include one or combinations of indium gallium zinc oxide (IGZO), indium gallium tinc oxide (IGTO), indium zinc oxide (IZO) and C-axis aligned crystalline (CAAC); accordingly, the transistor may be an oxide transistor (also referred to as an oxide thin film transistor). Alternatively, the material of the active pattern may include polysilicon (P—Si); accordingly, the transistor may be a polysilicon transistor. In a transistor, the active pattern may exhibit conductive characteristics under the driving of the gate and source voltages, so that the source and the drain are communicated; or exhibit pinch-off effect, so that the source and the drain are uncommunicated.

In some embodiments, all transistors in the pixel driving circuit are of the same type, for example, all transistors are oxide transistors or polysilicon transistors. In some other embodiments, there are at least two types of transistors in the pixel driving circuit. For example, the pixel driving circuit may include some oxide transistors and some polysilicon transistors.

In some examples, all transistors in the pixel driving circuit may all be P-type transistors. It will be noted that, the embodiments of the present disclosure include P-type transistors, but are not limited thereto. For example, one or more transistors in the pixel driving circuit provided in the embodiments of the present disclosure may adopt N-type transistors, as long as the connection between all electrodes of transistors of the N-type are correspondingly refer to the respective electrodes of the transistors of the P-type in the embodiments of the present disclosure, and a high-level voltage is provided for the corresponding gate.

The light-emitting panel 20 may emit white light, monochromatic light (light of a single color), or color-adjustable light.

For example, the light-emitting panel may emit white light. In this case, the light-emitting panel 20 may be used for lighting, i.e., may be applied to a lighting device. In a first case, the plurality of light-emitting devices 240 included in the light-emitting panel 20 all emit white light. In this case, a luminescent material of each light-emitting device 240 may include a mixed material of a red luminescent material, a green luminescent material, and a blue luminescent material. In this case, each light-emitting device 240 may be driven to emit light to emit white light. In a second case, a luminescent material of the red light-emitting devices may include a red luminescent material, a luminescent material of the green light-emitting devices may include a green luminescent material, and a luminescent material of the blue light-emitting devices may include a blue luminescent material. In this case, the luminance of the red light-emitting devices, the green light-emitting devices and the blue light-emitting devices may be controlled so that the red light-emitting devices, the green light-emitting devices and the blue light-emitting devices can achieve mixed light, and thus the light-emitting panel 20 emits white light.

For another example, the light-emitting panel 20 may emit monochromatic light. In this case, the light-emitting substrate 20 may be used for lighting (i.e., may be applied to a lighting device), or may be used for displaying monochromatic images or pictures (i.e., it may be applied to a display apparatus). In a first case, the plurality of light-emitting devices 240 included in the light-emitting panel 20 all emit monochromatic light (e.g., red light, green light or blue light). In this case, a luminescent material of each light-emitting device 240 includes a red luminescent material, a green luminescent material, or a blue luminescent material. In this case, each light-emitting device 240 may be driven to emit light, thereby emitting monochromatic light. In a second case, structures of the plurality of light-emitting devices 240 included in the light-emitting panel 20 are similar to structures of the plurality of light-emitting devices 240 described in the second case where the light-emitting panel 20 emits white light. In this case, the red light-emitting devices, green light-emitting devices or blue light-emitting devices are individually driven to achieve that the light-emitting panel 20 emits monochromatic light.

As another example, the light-emitting panel 20 may emit light with an adjustable color (i.e., colored light). In this case, the light-emitting panel 20 may be used to display images or pictures. That is, the light-emitting panel 20 may be applied to a display apparatus; alternatively, the light-emitting panel 20 may be applied to a lighting device. The structures of the plurality of light-emitting devices 240 included in the light-emitting panel 20 are similar to structures of the plurality of light-emitting devices 240 described in the second case where the light-emitting panel 20 emits white light. By controlling the luminance of each light-emitting device 240, the color and luminance of the mixed light emitted by the light-emitting panel 20 may be controlled to achieve color emission.

The light-emitting device 240 includes a first electrode 241, a light-emitting layer 243 and a second electrode 245 that are sequentially arranged in a direction from the substrate 210 to the circuit structure layer 220.

The first electrode 241 and the second electrode 245 may be transmissive electrodes, semi-transparent and semi-reflective electrodes, or reflective electrodes. The material of the transmissive electrode or the semi-transparent and semi-reflective electrode may include: a conductive oxide such as zinc oxide, indium oxide, tin oxide, indium tin oxide (ITO), indium zinc oxide (IZO), or fluorine-doped tin oxide, or a metal thin layer. The reflective electrode may include a reflective metal; for example, the reflective metal may be an opaque conductor such as aluminum (Al), silver (Ag), or gold (Au). The first electrode 241 and the second electrode 245 are of a single-layer or multi-layer structure. A layer where the first electrode 241 of the plurality of light-emitting devices 240 are located may be referred to as a first electrode pattern layer. A layer where the second electrodes 245 of the plurality of light-emitting devices 240 are located may be referred to as a second electrode pattern layer.

The types of the first electrode 241 and the second electrode 245 may be set according to the light-emitting mode of the light-emitting panel 20. For example, the light-emitting panel 20 may be divided into a top emission light-emitting panel, a bottom emission light-emitting panel or a double-side emission light-emitting panel according to the light-emitting mode. For example, in a case where the light-emitting panel 20 is a top emission light-emitting panel, the second electrode 245 may be a transmissive electrode, and the first electrode 241 may be a reflective electrode. For another example, in a case where the light-emitting panel 20 is a bottom emission light-emitting panel, the first electrode 241 is a transmissive electrode, and the second electrode 245 is a reflective electrode. For yet another example, in a case where the light-emitting panel 20 is a double-sided emission light-emitting panel, the first electrode 241 and the second electrode 245 are both transmissive electrodes.

One of the first electrode 241 and the second electrode 245 is a cathode, and the other of the first electrode 241 and the second electrode 245 is an anode. In some embodiments, the first electrode 241 may be an anode, and in this case, the second electrode 245 may be a cathode, and the light-emitting device 240 may be referred to as an “upright” light-emitting device accordingly. In some other embodiments, the first electrode 241 may be a cathode, and in this case, the second electrode 245 is an anode, and the light-emitting device 240 may be called an “inverted” light-emitting device accordingly.

In some embodiments, the anode may include a conductor having a high work function such as a metal, a conductive metal oxide, or a combination thereof. The metal may be nickel, platinum, vanadium, chromium, copper, zinc, gold, or an alloy of the above; the conductive metal oxide may be zinc oxide, indium oxide, tin oxide, indium tin oxide (ITO), indium zinc oxide (IZO), or fluorine-doped tin oxide. The combination of the metal and the conductive metal oxide may be ZnO and Al, SnO₂ and Sb, or ITO/Ag/ITO, but is not limited thereto.

The cathode may include a conductor such as a metal, a conductive metal oxide, and/or a conductive polymer having a lower work function than that of the anode. The cathode may include a metal (such as aluminum, magnesium, calcium, sodium, potassium, titanium, indium, yttrium, lithium, gadolinium, silver, tin, lead, cesium, barium, or an alloy thereof), or a multi-layer structure (such as LiF/Al, Li₂O/Al, Liq/Al, LiF/Ca, and BaF₂/Ca), or a conductive metal oxide (such as zinc oxide, indium oxide, tin oxide, indium tin oxide (ITO), indium zinc oxide (IZO), or fluorine-doped tin oxide), but is not limited thereto.

The work function of the anode may be higher than that of the cathode. For example, the work function of the anode may be in a range of approximately 4.5 eV to approximately 5.0 eV, and the work function of the cathode may be in a range of approximately 4.0 eV to approximately 4.7 eV. Within this range, the work function of the anode may be in a range of, for example, approximately 4.6 eV to approximately 4.9 eV or approximately 4.6 eV to approximately 4.8 eV, and the work function of the cathode may be in a range of, for example, approximately 4.0 eV to approximately 4.6 eV or approximately 4.3 eV to approximately 4.6 eV.

The material of the light-emitting layer 243 may be a luminescent material. For example, the luminescent material may be luminescent particles. The luminescent particles may be quantum dots (the quantum dots may be semiconductor nanocrystals), and in this case, the light-emitting device 240 may be referred to as a quantum dot light-emitting diode (QLED) correspondingly. The manufacturing technologies of the light-emitting layer 243 mainly include inkjet printing technology, photolithography technology, transfer technology, etc. The photolithography technology is the most promising method for manufacturing a high-resolution QLED. The photolithography technology may be a technology that uses exposure and development to achieve quantum dot patterning.

The light-emitting principle of the light-emitting device 240 is: by using a circuit connected an anode to a cathode, the anode is used to inject holes into the light-emitting layer 243, and the cathode is used to inject electrons into the light-emitting layer 243. The formed electrons and holes form excitons in the light-emitting layer 243, and the excitons return to the ground state through radiation transition, and thus photons are released.

The light-emitting device 240 further includes a first carrier transport layer 242 and a second carrier transport layer 244; that is, the first electrode 241, the first carrier transport layer 242, the light-emitting layer 243, the second carrier transport layer 244 and the second electrode 245 are sequentially stacked.

One of the first carrier transport layer 242 and the second carrier transport layer 244 is a hole transport layer, and the other is an electron transport layer. In some embodiments, in an “upright” light-emitting device, the first electrode 241 may be an anode. In this case, the first carrier transport layer 242 is a hole transport layer, and the second carrier transport layer 244 is an electron transport layer. In some other embodiments, in an “inverted” light-emitting device, the first electrode 241 may be a cathode. In this case, the first carrier transport layer 242 is an electron transport layer, and the second carrier transport layer 244 is a hole transport layer. The electron transport layer may be of a single-layer structure or a multi-layer structure. The hole transport layer may be of a single-layer structure or a multi-layer structure. The carriers may be holes or electrons.

The material of the hole transport layer is a p-type semiconductor. The use of p-type semiconductors may promote the transport and injection of holes and reduce the ability to transport electrons, so that the hole transport layer may promote the transport rate of holes and reduce the transport rate of electrons. For example, the p-type semiconductor may be a p-type semiconductor oxide. The ratio of the number of metal atoms to that of oxygen atoms in the p-type semiconductor oxide is not strictly in accordance with the ratio of the number of atoms in its chemical formula, but the number of oxygen atoms is slightly great, and the structural defects present in the oxide are metal ion vacancies. The p-type semiconductor oxide may be an oxide such as NiOx, MoOx, WOx, VOx or CrOx. For another example, the p-type semiconductor may also be a p-type semiconductor non-oxide, such as MoS₂, Cul, SnS, or CuSCN.

The material of the electron transport layer is an n-type semiconductor. The use of n-type semiconductors may promote the transmission and injection of electrons and reduce the ability to transmit holes, so that the electron transport layer may promote the transmission rate of electrons and reduce the transmission rate of holes. For example, the n-type semiconductor may be an n-type semiconductor oxide. The ratio of the number of metal atoms to that of oxygen atoms in the n-type semiconductor oxide is not strictly in accordance with the stoichiometric ratio, but the number of metal atoms is slightly great. The n-type semiconductor oxide may be ZnMgO, ZnO, TiO₂, SnO₂ or CdO, etc. For another example, the n-type semiconductor may also be an n-type semiconductor non-oxide, such as CsS, ZnS, ZnF₂ or Cs₂Se.

At least one of the first carrier transport layer 242 and the second carrier transport layer 244 is a specific carrier transport layer TD. For example, the first carrier transport layer 242 is a specific carrier transport layer TD. For another example, the second carrier transport layer 244 is a specific carrier transport layer TD. For yet another example, the first carrier transport layer 242 and the second carrier transport layer 244 are both specific carrier transport layers TD; it can be understood that the same improvements are made to the first carrier transport layer 242 and the second carrier transport layer 244.

In the related art, two adjacent light-emitting devices 240 may be referred to as a first light-emitting device and a second light-emitting device; since the cathodes of the plurality of light-emitting devices 240 are connected, there is a voltage drop between the first electrode 241 of the first light-emitting device and the second electrode 245 of the second light-emitting device; due to the voltage drop, the carriers of the first light-emitting device move to the specific carrier transport layer TD of the second light-emitting device through the specific carrier transport layer TD of the first light-emitting device; then, the carriers of the first light-emitting device and the carriers of the second light-emitting device are both moved to the light-emitting layer 243 of the second light-emitting device for combination to emit light, resulting in a change in the light emitted by the second light-emitting device, i.e., resulting in crosstalk for the second light-emitting device. In this way, when the first light-emitting device is emitting light, the second light-emitting device will also emit light, so that the light-emitting panel 20 emits uneven light and the display effect is poor. The description below will be made to ameliorate the problem that the carriers of the first light-emitting device move to the specific carrier transport layer TD of the second light-emitting device through the specific carrier transport layer TD of the first light-emitting device.

The following description will be made by taking an example in which the first carrier transport layer 242 is the specific carrier transport layer TD.

In the embodiments of the present disclosure, the specific carrier transport layer TD includes a plurality of first portions D1 and a plurality of second portions D2. The second portion D2 is connected between at least two (e.g., two or more) first portions D1. For example, in a case where the plurality of pixel openings 231 are distributed in an array, the second portion D2 may be understood as a portion of the specific carrier transport layer TD located between two pixel openings 231. In this case, the second portion D2 is connected between the two first portions D1. The number of the first portions D1 is equal to the number of the pixel openings 231, and the first portions D1 correspond to the pixel openings 231 in a one-to-one manner.

In some examples, referring to FIG. 2, the pixel opening 231 may be understood as including an opening region KT and two side walls CB located on two sides of the opening region KT; in this case, the first portion D1 is located in the pixel opening 231, which may be understood that the first portion D1 is directly opposite to the opening region KT and the two side walls CB, i.e., an orthographic projection of the first portion D1 on a plane where the substrate 210 is located coincides with an orthographic projection of the opening region KT and the two side walls CB on the plane where the substrate 210 is located. In these examples, the second portion D2 includes a transition surface PT and does not include an inclined surface QX, that is, the first portion D1 includes the inclined surface QX. The transition surface PT is connected between two inclined surfaces QX.

In some other examples, referring to FIG. 3, the pixel opening 231 may be understood as including an opening region KT, and does not including the two side walls CB located on two sides of the opening region; in this case, the first portion D1 is located in the pixel opening 231, which may be understood that the first portion D1 is directly opposite to the opening region KT, i.e., an orthographic projection of the first portion D1 on the plane where the substrate 210 is located coincides with an orthographic projection of the opening region KT on the plane where the substrate 210 is located. In these examples, the second portion D2 includes the transition surface ZB and two inclined surfaces QX, that is, the first portion D1 does not include the inclined surface QX.

The second portion D2 is doped with a first material 250, and is used to play a role of conductivity isolation for at least two first portions D1. In this way, the first material 250 doped in the second portion D2 plays a role of blocking carriers, so that the voltage drop between the first portion D1 and the second portion D2 is very small, thereby reducing the movement of carriers to the adjacent light-emitting device 240.

For convenience of explanation, herein, the second portion D2 is referred to as an initial portion before being doped with the first material 250, and the first portion D1 and the initial portion are made of the same material, which may be referred to as a second material. The material for forming the specific carrier transport layer TD refers to the second material. The material formed after the second portion D2 is doped with the first material 250 is referred to as the third material; that is, the second portion D2 is doped with the first material 250, which may be understood as that the initial portion is doped with the first material 250 to form the second portion D2, and the material of the second portion D2 is the third material.

In some embodiments, the material of the first portion D1 and the second portion D2 that is doped with the first material 250 form a pn junction, which may be understood that the material of the first portion D1 and the third material of the second portion D2 form a pn junction at the interface between the first portion D1 and the second portion D2. The pn junction blocks the transfer of the carriers in the first portion D1 to the second portion D2, so that the pn junction may play a role of conductivity isolation for at least two first portions D1. The doping concentration of the first material 250 is in a range of 10¹⁷ cm⁻¹ to 10²⁰ cm⁻¹, such as 10¹⁷ cm⁻¹, 10¹⁸ cm⁻¹, 10¹⁹ cm⁻¹, or 10²⁰ cm⁻¹, which may allow the second material of the initial portion forms the third material of the second portion D2. The fermi energy level position of the third material and the fermi energy level of the second material are located on different sides (i.e., two sides) of the band gap center, so that the formed third material and the second material of the first portion D1 form a pn junction.

For example, for an “inverted” light-emitting device, in a case where the first carrier transport layer is an electron transport layer, and the second material is an n-type semiconductor, the second material of the initial portion is doped with the first material 250 to form the third material of the second portion D2; that is, the third material of the second portion D2 is formed by the second material of the initial portion and the first material 250. The formed third material and the second material of the first portion D1 form a pn junction. The description of the n-type semiconductor may refer to the related description that the material of the electron transport layer is the n-type semiconductor.

In this case, for example, if the first material 250 includes one material, the first material 250 should satisfy that the cation valence of the first material 250 is smaller than the cation valence of the second material. For another example, if the first material 250 includes one material, the first material 250 should satisfy that the anion valence of the first material 250 is smaller than the anion valence of the second material. For yet another example, if the first material 250 includes multiple materials, the first material 250 should satisfy that the cation valence of the first material 250 is smaller than the cation valence of the second material, and the anion valence of the first material 250 is smaller than the anion valence of the second material. Herein, the cationic valence of the first material 250 may be understood as the cationic valence of the first material 250 when all the electrons in the outermost shell of the first material 250 are lost; the anionic valence of the first material 250 may be understood as the anionic valence of the first material 250 when the number of the electrons in the outermost shell of the first material 250 reach 8 or 2.

In some examples, in a case where the second material is n-type ZnO, the cations in the second material are divalent. In this case, the first material 250 may be a material capable of forming monovalent cations. For example, the first material 250 may be Mg, Ag, Li, etc. The anions in the second material are negative divalent. In this case, the first material 250 may also be a material capable of forming negative trivalent, negative tetravalent, negative pentavalent, negative hexavalent, or negative heptavalent anions. For example, the first material 250 may be S, N, etc.

For example, the initial portion of n-type ZnO is doped with the first material 250 of Ag, or N, or Ag and N, so that the third material of p-type ZnO is formed through the initial portion of n-type ZnO, and in this case, the third material of p-type ZnO and the first portion D1 of n-type ZnO may form a pn junction.

As another example, for an “upright” light-emitting device, in a case where the first carrier transport layer is a hole transport layer, and the second material is a p-type semiconductor, the second material of the initial portion is doped with the first material 250 to form a third material; that is, the third material of the second portion D2 is formed by the second material of the initial portion and the first material 250. The formed third material and the second material of the first portion D1 form a pn junction. The formed pn junction may block the transfer of the holes to the first portion D1. The description of the p-type semiconductor may refer to the related description that the material of the hole transport layer is a p-type semiconductor.

For example, in the case where the first material 250 includes one material, the first material 250 should satisfy that the cation valence of the first material 250 is greater than the cation valence of the second material. For another example, in the case where the first material 250 includes one material, the first material 250 should satisfy that the anion valence of the first material 250 is greater than the anion valence of the second material. For yet another example, in the case where the first material 250 includes multiple materials, the first material 250 should satisfy that the cation valence of the first material 250 is greater than the cation valence of the second material, and the anion valence of the first material 250 is greater than the anion valence of the second material.

In the case where the second material is NiOx, the cation valence in the second material are, for example, divalent. In this case, the first material 250 may be a material capable of forming positive trivalent, positive tetravalent, positive pentavalent, positive hexavalent, or positive heptavalent cations. For example, the first material 250 may be Si, Al, Ga, In, etc. The anions in the second material are negative divalent anions. In this case, the first material 250 may be a material capable of forming negative monovalent anions. For example, the first material 250 may be a halogen element.

In some other embodiments, the second portion D2 is doped with the first material 250 to form a compensation semiconductor; that is, the third material is a compensation semiconductor. The formed compensation semiconductor reduces the mobility of carriers, so that the compensation semiconductor plays a role of conductivity isolation for the at least two first portions D1. The doping concentration of the first material 250 is in a range of 0.1 cm⁻¹ to 10¹⁷ cm⁻¹, such as 0.1 cm⁻¹, 10³ cm⁻¹, 10⁵ cm⁻¹, 10¹⁰ cm⁻¹, 10¹³ cm⁻¹ or 10¹⁶ cm⁻¹, and a ratio of the carrier concentration of the first material 250 to the carrier concentration of the material of the specific carrier transport layer TD (i.e., the second material) is in a range of 0.9 to 1.1 (e.g., 0.9, 0.95, 1, 1.05, 1.1), which may enable the second material of the initial portion to form a third material; the third material is a compensation semiconductor, and the fermi level of the third material is located near the band gap center (e.g., on the band gap center). In these embodiments, the doping concentration of the first material does not include 10¹⁷ cm⁻¹. There is a relationship between the doping concentration of the first material 250 and the carrier concentration formed by the first material 250; that is, the first material 250 with this doping concentration may ionize carriers, and the concentration of the ionized carriers may be referred to as the carrier concentration formed by the first material 250.

For example, for an “inverted” light-emitting device, in the case where the first carrier transport layer is an electron transport layer, and the second material is an n-type semiconductor, the second material of the second part D2 is doped with the first material 250 to form the third material, that is, the third material is formed by the second material of the initial portion and the first material 250. In this case, the third material is a compensation semiconductor. The formed compensation semiconductor may reduce the mobility of electrons, thereby blocking the transfer of the electrons to the second portion D2. The description of the n-type semiconductor may refer to the related description that the material of the electron transport layer is the n-type semiconductor. The description of the first material 250 may refer to the related description of the first material 250 of the “inverted” light-emitting device above.

As another example, for an “upright” light-emitting device, in the case where the first carrier transport layer is a hole transport layer, and the second material is a p-type semiconductor, the second material of the initial portion is doped with the first material 250 to form the third material, that is, the third material is formed by the second material of the initial portion and the first material 250. The third material is a compensation semiconductor; the formed compensation semiconductor may block the transfer of the holes to the first portion D1. The description of the p-type semiconductor may refer to the related description that the material of the hole transport layer is a p-type semiconductor. The description of the first material 250 may refer to the related description of the first material 250 in the “upright” light-emitting device above.

In some other embodiments, the first material 250 includes at least one of carbon (C), silicon (Si), germanium (Ge), tin (Sn), plumbum (Pb), and flerovium (Fl). For example, the first material 250 includes silicon. In this case, the second portion D2 is doped with the first material 250, which may be understood that the second material is doped with the first material 250 to change the orbit of electrons in the second material, thereby reducing the electron mobility of the second material. That is, the impurity scattering is adopted. Carbon (C), silicon (Si), germanium (Ge), tin (Sn), plumbum (Pb) and flerovium (Fl) are elements located in Group IVA of the periodic table and are referred to as carbon group elements.

In some other embodiments, for example, the cationic valence of the first material 250 is the same as the cationic valence of the specific carrier transport layer TD, and the band gap of the material formed by the cations of the first material 250 and the anions of the specific carrier transport layer TD is greater than the band gap of the specific carrier transport layer TD (i.e., the second material). In this way, the band gap of the material formed by the first material 250 and the material of the specific carrier transport layer TD (e.g., ZnMgO mentioned below) is greater than the band gap of the second material (e.g., ZnO); the principle that the larger the band gap, the larger the energy barrier may be used, thereby further increasing the energy barrier of the second portion D2; the increased energy barrier may prevent carriers from diffusing to the adjacent first portion D1.

For another example, the anion valence of the first material 250 is the same as the anion valence of the specific carrier transport layer TD, and the band gap of the material formed by the anion in the first material 250 and the cation in the specific carrier transport layer TD is greater than the band gap of the specific carrier transport layer TD (i.e., the second material). In this way, the band gap of the material formed by the first material 250 and the material of the specific carrier transport layer TD (e.g., ZnSO mentioned below) is greater than the band gap of the second material (e.g., ZnO). The principle that the larger the band gap, the larger the energy barrier is used, the energy barrier of the second portion D2 is thereby increased, and the increased energy barrier may prevent carriers from diffusing to the adjacent first portion D1.

In some examples, the second material is ZnO. The first material 250 includes at least one of magnesium (Mg), calcium (Ca), or sulfur (S). For example, in the case where ZnO is doped with S, the band gap of ZnS is greater than the band gap of ZnO, so that the band gap of the formed ZnSO is greater than the band gap of ZnO. For another example, in a case where ZnO is doped with Mg, the band gap of MgO is greater than the band gap of ZnO, so that the band gap of the formed ZnMgO is greater than the band gap of ZnO.

In some examples, the first portion D1 is doped with the first material 250, and the doping concentration of the first material 250 in the second portion D2 is greater than the doping concentration of the first material 250 in the first portion D1. For example, in a case where the cation valence formed by the first material 250 is the same as the cation valence of the specific carrier transport layer TD, the doping concentration of the first material 250 in the second portion D2 is greater than the doping concentration of the first material 250 in the first portion D1. For another example, in a case where the anion valence formed by the first material 250 is the same as the anion valence of the specific carrier transport layer TD, the doping concentration of the first material 250 in the second portion D2 is greater than the doping concentration of the first material 250 in the first portion D1. In these examples, the first portion D1 is doped with the first material 250, which may be understood as the material of the first portion D1 being the fourth material; that is, the material of the first portion D1 is not the second material. Herein, when it is not stated that the material of the first portion D1 is the fourth material, the material of the first portion D1 is the second material.

In some other embodiments, as shown in FIGS. 2 and 3, the doping concentration of the first material 250 in the second portion D2 decreases sequentially in a direction from a middle ZB of the second portion D2 to an end DB of the second portion D2. In this way, the amount of doped first material 250 near the first portion D1 is less, so that the first portion D1 is prevent from being doped with the first material 250. The middle ZB of the second portion D2 may be understood as a portion at the middlemost position (i.e., the center) of the second portion D2. For example, by means of high temperature diffusion, the first material 250 is diffused from the middle ZB of the second portion D2 to the end DB of the second portion D2, so that the doping concentration of the first material 250 decreases from the middle ZB of the second portion D2 to the end DB of the second portion D2.

In some other embodiments, since the number of carriers in the specific carrier transport layer TD proximate to the light-emitting layer is less than the number of carriers in the specific carrier transport layer TD away from the light-emitting layer, the doping concentration of the first material 250 in the second portion D2 decreases sequentially in the first direction. The first direction is a direction from the specific carrier transport layer to the light-emitting layer. For example, in the case where the specific carrier transport layer TD is the first carrier transport layer 242, the first direction is a direction from the first carrier transport layer 242 to the light-emitting layer 243. For example, in a case where the specific carrier transport layer TD is the second carrier transport layer 244, the first direction is a direction from the second carrier transport layer 244 to the light-emitting layer 243. For example, in a case where the specific carrier transport layer TD is the first carrier transport layer 242 and the second carrier transport layer 244, the first direction is the direction from the first carrier transport layer 242 to the light-emitting layer 243 and the direction from the second carrier transport layer 244 to the light-emitting layer 423. In this case, the first direction may be understood as two opposite directions.

In an example of the present disclosure, a comparative solution of a light-emitting panel is provided. In the comparative solution, the light-emitting panel includes a carrier transport layer, and the position and connection of the carrier transport layer may respectively refer to the relevant description of the position and connection of the specific carrier transport layer in these embodiments. The material of the carrier transport layer is different from the material of the specific carrier transport layer, and the material of the carrier transport layer is nanoparticles. The third portion of the carrier transport layer formed by the nanoparticles (the third portion may be understood as the second portion D2 in these embodiments, but the materials of the two are different) is roughed, so that the film of the third portion is thinned or even disconnected during the evaporation process, thereby reducing the leakage of carriers into the adjacent light-emitting device 240. However, in a case where the thickness of the third part is small, it may cause the communication between the first electrode 241 and the light-emitting layer 243, resulting in carrier leakage; in addition, the manner of performing a rough treatment on the third portion is suitable for evaporation and is not suitable for magnetron sputtering, sol-gel, spin coating and other processes.

Compared with the comparative solution, in these embodiments, the method of forming the specific carrier transport layer TD is not limited. For example, the specific carrier transport layer TD may be formed by magnetron sputtering, physical vapor deposition, chemical vapor deposition, sol-gel method, solution spin coating and other processes. Thus, the second portion D2 of the specific carrier transport layer TD formed by the above process is doped with the first material 250. For example, the specific carrier transport layer TD is formed by magnetron sputtering, and the second portion D2 of the formed specific carrier transport layer TD is doped with the first material 250. In addition, compared with the comparative solution, in these embodiments, the surface roughness of the surface of the specific carrier transport layer TD away from the pixel definition layer 230 is smaller; for example, the surface roughness is in a range of 0 to 5 nm (e.g., 0, 1 nm, 2 nm, 3 nm, 4 nm, or 5 nm). Compared with the nanoparticles (which are organic materials) in the comparative solution, the material of the specific carrier transport layer TD in the embodiments may be an inorganic material.

In some embodiments, the light-emitting device 240 includes at least one of an electron injection layer, a hole blocking layer, a hole injection layer, and an electron blocking layer. In some examples, in an “upright” light-emitting device, in a direction from the substrate 210 to the circuit structure layer 220, an anode, a hole injection layer, a hole transport layer, an electron blocking layer, a light-emitting layer 243, a hole blocking layer, an electron transport layer and an electron injection layer and a cathode are sequentially arranged. In some examples, in an “inverted” light-emitting device, in the direction from the substrate 210 to the circuit structure layer 220, a cathode, an electron injection layer, an electron transport layer, a hole blocking layer, a light-emitting layer 243, an electron blocking layer, a hole transport layer, a hole injection layer and an anode are sequentially arranged.

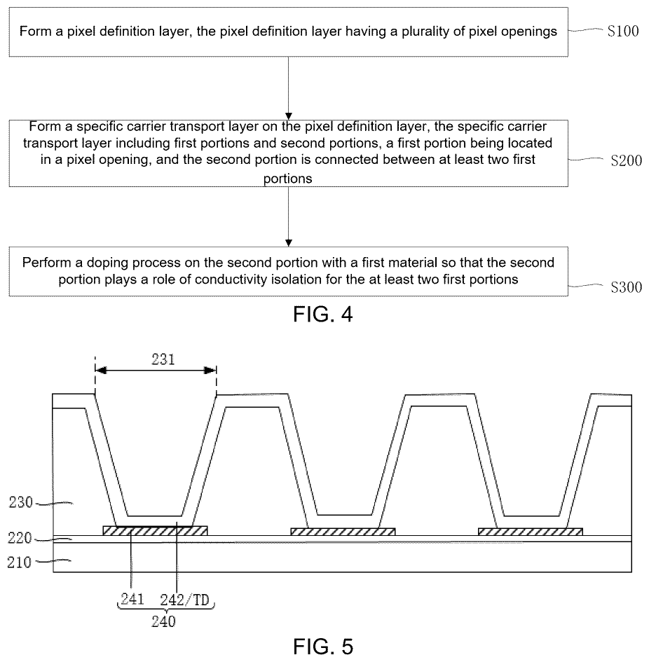

Some embodiments of the present disclosure provide a manufacturing method for a light-emitting panel. Referring to FIG. 4, the manufacturing method includes: step S100, step S200, and step S300. The process diagrams of the manufacturing method for the light-emitting panel shown in FIG. 5, FIGS. 7 to 9, and FIGS. 11 to 16 hereinafter are all illustrated by considering the light-emitting panel shown in FIG. 2 as an example.

In step S100, referring to FIG. 5, a pixel definition layer 230 is formed. The pixel definition layer 230 has a plurality of pixel openings 231.

In step S200, a specific carrier transport layer TD is formed on the pixel definition layer 230. The specific carrier transport layer TD includes first portions D1 and second portions D2, a first portion D1 is located in a pixel opening 231, and the second portion D2 is connected between at least two first portions D1.

In step S300, a doping process is performed on the second portion (here, the second portion may be understood as an initial potion) with the first material 250 so that the second portion plays a role of conductivity isolation for at least two first portions D1. For example, the second portion D2 is doped with the first material 250 by ion implantation.

The description of steps S100 to S300 may refer to the related description of the above-mentioned light-emitting panel 20. For the specific carrier transport layer TD formed by the manufacturing method for the light-emitting panel 20, reference may be made to the related description of the specific carrier transport layer TD in the light-emitting panel 20 above.

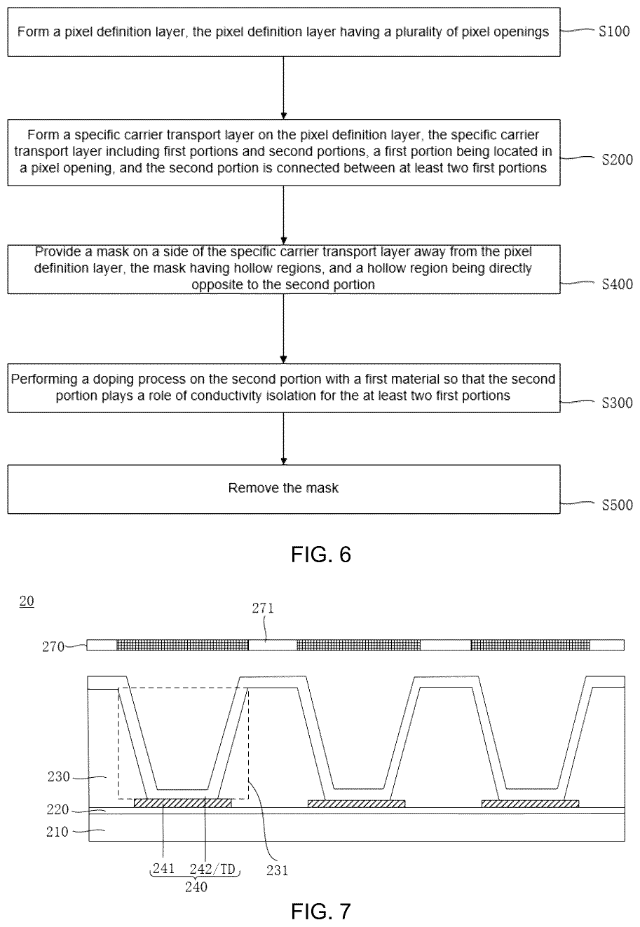

In some embodiments, referring to FIG. 6, between steps S200 and S300, the manufacturing method further includes the step S400.

In the step S400, referring to FIG. 7, a mask 270 is provided on a side of the specific carrier transport layer TD away from the pixel definition layer 230. The mask 270 has hollow regions, and the hollow region is directly opposite to the second portion D2. The shape of the hollow region may be designed according to the shape of the second portion D2; for example, the shape of the hollow region may be the same as a contour of an orthographic projection of the second portion D2 on the substrate. In this way, the initial portion (refer to the description of the initial portion in the light-emitting panel) is doped with the first material 250 by using the hollow region to form the second portion D2. The first portion D1 is protected by the mask 270, thereby preventing the first portion D1 from being doped with the first material 250.

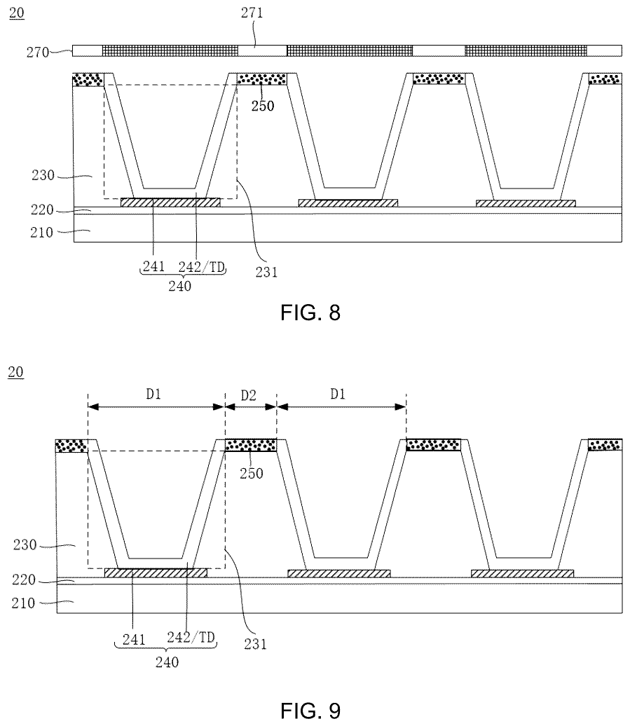

In the step S300, referring to FIG. 8, a doping process is performed on the second portion (here, the second portion may be understood as an initial potion) with the first material 250.

In some examples, after the step 300, the manufacturing method further includes step S500.

In the step S500, referring to FIG. 9, the mask 270 is removed.

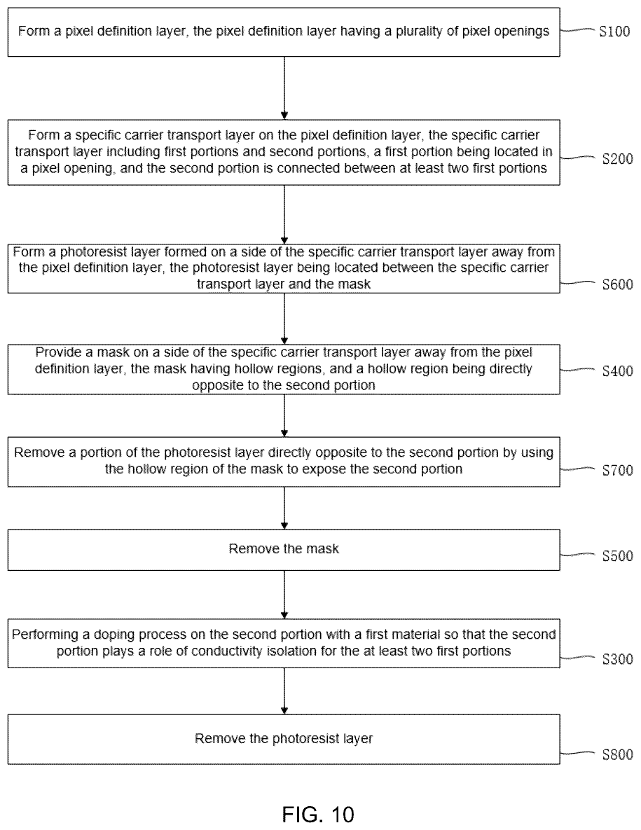

In some other examples, referring to FIG. 10, between the step S200 and step S400, the method further includes step S600.

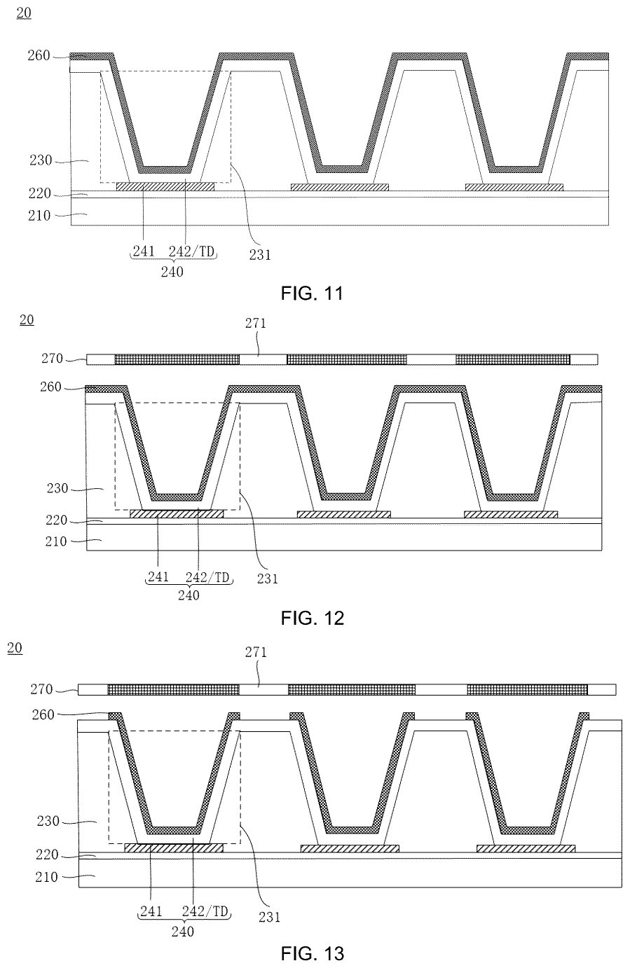

In the step S600, referring to FIG. 11, a photoresist layer 260 is formed on a side of the specific carrier transport layer TD away from the pixel definition layer 230. The photoresist layer 260 is located between the specific carrier transport layer TD and the mask 270.

In the step S400, referring to FIG. 12, a mask 270 is provided on a side of the specific carrier transport layer TD away from the pixel definition layer 230; the mask 270 has hollow regions, and the hollow region is directly opposite to the second portion D2. There is a gap between the mask 270 and the photoresist layer 260.

Between the step S400 and step S300, the method further includes step S700 and step S500.

In the step S700, referring to FIG. 13, the portion of the photoresist layer 260 directly opposite to the second portion D2 is removed by using the hollow region of the mask 270 to expose the second portion D2; and the portion of the photoresist layer 260 directly opposite to the first portion D1 is retained. In some examples, exposure and development are performed to remove the portion of the photoresist layer 260 that is directly opposite to the second portion D2. The light used for exposure may be, for example, ultraviolet rays (UV).

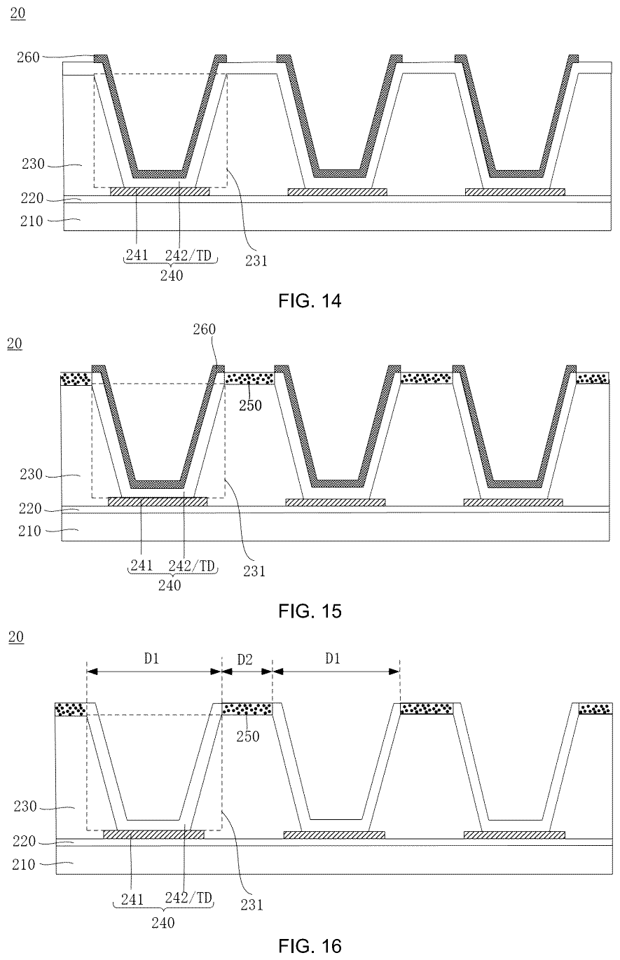

In the step S500, referring to FIG. 14, the mask 270 is removed.

In the step S300, referring to FIG. 15, a doping process is performed on the second portion D2 (which may be understood as the initial portion) with the first material 250. In this way, by removing the portion of the photoresist layer 260 directly opposite to the second portion D2, the initial portion may be doped with the first material to form the second portion D2. In addition, the remaining photoresist layer 260 may prevent the first portion D1 from being doped with the first material 250.

After the step 300, the method further includes step S800.

In the step S800, referring to FIG. 16, the photoresist layer 260 (the photoresist layer 260 may be understood as a portion of the photoresist layer 260 directly opposite to the first portion D1) is removed; and annealing is performed. After the step of removing the photoresist layer 260, processes for forming other film layers may be performed, for example, forming the light-emitting layer 243.

Herein, “directly opposite to” may be understood as an orthographic projection of one on a first plane coincides with an orthographic projection of the other on the first plane. For example, the portion of the photoresist layer 260 that is directly opposite to the second portion D2 may be understood as the portion of the photoresist layer 260 that is directly opposite to the second portion D2; that is, an orthographic projection of the portion of the photoresist layer 260 on a plane where the substrate 210 is located coincides with an orthographic projection of the second portion D2 on the plane where the substrate 210 is located. For example, the hollow region is directly opposite to the second portion D2, which may be understood that the orthographic projection of the hollow region on the plane where the substrate 210 is located coincides with the orthographic projection of the second portion D2 on the plane where the substrate 210 is located.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

What is claimed is:

1. A light-emitting panel, comprising:
a pixel definition layer having a plurality of pixel openings; and
a specific carrier transport layer including first portions and a second portion, wherein a first portion is located in a pixel opening, and the second portion is connected between at least two first portions; the second portion doped with a first material is configured to play a role of conductivity isolation for the at least two first portions.

2. The light-emitting panel according to claim 1, wherein the specific carrier transport layer includes:
a pn junction formed by the second portion doped with the first material and the first portion, and the pn junction is configured to play a role of conductivity isolation for the at least two first portions.

3. The light-emitting panel according to claim 2, wherein
a doping concentration of the first material is in a range of 10¹⁷ cm⁻¹ to 10²⁰ cm⁻¹.

4. The light-emitting panel according to claim 1, wherein the specific carrier transport layer includes:
a compensation semiconductor formed by the second portion doped with the first material, and the compensation semiconductor is configured to play a role of conductivity isolation for the at least two first portions.

5. The light-emitting panel according to claim 4, wherein
a doping concentration of the first material is in a range of 0.1 cm⁻¹ to 10¹⁷ cm⁻¹, a ratio of a carrier concentration of the first material to a carrier concentration of the specific carrier transport layer is in a range of 0.9 to 1.1.

6. The light-emitting panel according to claim 2, wherein
a material for forming the specific carrier transport layer includes a p-type semiconductor; a cation valence of the first material is greater than a cation valence of the material for forming the specific carrier transport layer, and/or an anion valence of the first material is greater than an anion valence of the material for forming the specific carrier transport layer;
or
the material for forming the specific carrier transport layer includes an n-type semiconductor, the cation valence of the first material is smaller than the cation valence of the material for forming the specific carrier transport layer, and/or the anion valence of the first material is smaller than the anion valence of the material for forming the specific carrier transport layer.

7. The light-emitting panel according to claim 1, wherein
the first material includes at least one of carbon, silicon, germanium, tin, plumbum, and flerovium.

8. The light-emitting panel according to claim 1, wherein
a cation valence of the first material is the same as a cation valence of the specific carrier transport layer, and a band gap of a material formed by cations of the first material and anions of a material for forming the specific carrier transport layer is greater than a band gap of the specific carrier transport layer;
or
an anion valence of the first material is the same as an anion valence of the specific carrier transport layer, and a band gap of a material formed by anions of the first material and cations of the material for forming the specific carrier transport layer is greater than the band gap of the specific carrier transport layer.

9. The light-emitting panel according to claim 8, wherein
the first portion is a portion doped with a first material, and a doping concentration of the first material in the second portion is greater than a doping concentration of the first material in the first portion.

10. The light-emitting panel according to claim 1, wherein
the second portion includes two inclined surfaces and a transition surface located between the two inclined surfaces.

11. The light-emitting panel according to claim 1, wherein
in a direction from a middle of the second portion to an end of the second portion, a doping concentration of the first material in the second portion decreases sequentially.

12. The light-emitting panel according to claim 1, further comprising:
a light-emitting layer stacked with the specific carrier transport layer;
wherein in a direction from the specific carrier transport layer to the light-emitting layer, a doping concentration of the first material in the second portion decreases successively.

13. The light-emitting panel according to claim 1, wherein
a surface roughness of a surface of the specific carrier transport layer away from the pixel definition layer is in a range of 0 to 5 nm.

14. The light-emitting panel according to claim 1, wherein
a material of the specific carrier transport layer is an inorganic material.

15. The light-emitting panel according to claim 1, further comprising: a first electrode, a first carrier transport layer, a light-emitting layer, a second carrier transport layer and a second electrode that are stacked in sequence, a material of the light-emitting layer being quantum dots; wherein
the specific carrier transport layer is at least one of the first carrier transport layer and the second carrier transport layer.

16. A manufacturing method for a light-emitting panel, comprising:
forming a pixel definition layer, the pixel definition layer having pixel openings;
forming a specific carrier transport layer on the pixel definition layer; wherein the specific carrier transport layer includes first portions and a second portion, a first portion is located in a pixel opening, and the second portion is connected between at least two first portions; and
performing a doping process on an initial portion of the specific carrier transport layer with a first material to form the second portion, so that the second portion plays a role of conductivity isolation for the at least two first portions.

17. The manufacturing method for the light-emitting panel according to claim 16, wherein
after forming the specific carrier transport layer on the pixel definition layer and before performing the doping process on the initial portion of the specific carrier transport layer with the first material, the method further comprises:
providing a mask on a side of the specific carrier transport layer away from the pixel definition layer; wherein the mask has hollow regions, and a hollow region is directly opposite to the initial portion.

18. The manufacturing method for the light-emitting panel according to claim 17, wherein
before providing the mask on the side of the specific carrier transport layer away from the pixel definition layer, the method further comprises:
forming a photoresist layer on the side of the specific carrier transport layer away from the pixel definition layer, the photoresist layer being located between the specific carrier transport layer and the mask; and
after providing the mask on the side of the specific carrier transport layer away from the pixel definition layer, the method further comprises:
removing a portion of the photoresist layer directly opposite to the initial portion by using the hollow region of the mask, so as to expose the initial portion; and
after performing the doping process on the initial portion with the first material, the method further comprises:
removing the photoresist layer.

19. The manufacturing method for the light-emitting panel according to claim 16, wherein
performing the doping process on the initial portion with the first material includes:
performing the doping process on the initial portion with the first material by ion implantation.

20. A light-emitting device, comprising:
the light-emitting panel according to claim 1.
